(19) United States
(12) Patent Application Publication
(10) Pub. No.: US 2026/0029431 A1
(43) Pub. Date: Jan. 29, 2026

(54) Optical Probing System with Multi-Signal Modulation and Demodulation

(71) Applicant: PMK Mess- und Kommunikationstechnik, GmbH, Bad Soden am Taunus (DE)

(72) Inventors: Juergen Trueller, Gernheim (DE); Jurij Weber, Schwalbach am Taunus (DE); Kai Klein, Neu Anspach (DE); Richard Booman, Lake Oswego, OR (US); Michael J. Mende, Portland, OR (US); Mark Heimann, Bad Soden am Taunus (DE)

(21) Appl. No.: 19/278,753

(22) Filed: Jul. 23, 2025

Related U.S. Application Data
(60) Provisional application No. 63/674,276, filed on Jul. 23, 2024.

(51) Int. Cl. G01R 1/07; G01R 1/24; G01R 31/265; G01R 31/28

(52) U.S. Cl. CPC G01R 1/071; G01R 1/24; G01R 31/2656; G01R 31/2822

(57) ABSTRACT

An optical probing system transmits high-fidelity analog signals from a device under test (DUT) to a measurement instrument. The system receives a differential input signal and separates it into a high-frequency (HF) component and a low-frequency (LF) component. Each component is independently modulated using distinct analog modulation techniques and transmitted over separate optical fibers. The architecture maintains galvanic isolation between the input and output devices and enables independent transmission of signal portions optimized for bandwidth and accuracy. The signals are demodulated, delay-aligned, and recombined in the analog domain to produce a reconstructed full-bandwidth output.

### CROSS REFERENCE TO RELATED APPLICATION

This application claims priority to U.S. provisional application No. 63/674,276, filed Jul. 23, 2024, and entitled Optical Probing System with Multi-Signal Modulation, the entire contents of which are herein incorporated by reference.

### FIELD OF THE DISCLOSURE

The present invention pertains to the field of test and measurement probes, and more particularly, to an optical-analog optical probing system with multiple analog signal modulation and demodulation.

### BACKGROUND OF THE DISCLOSURE

The adoption of wide-bandgap semiconductor technologies—such as Gallium Nitride (GaN) and Silicon Carbide (SiC)—has enabled significant improvements in power conversion efficiency and switching performance. However, these advantages come with the tradeoff of dramatically increased switching speeds and elevated voltage slew rates, which impose demanding requirements on signal bandwidth, dynamic range, and measurement accuracy. Fast switching events, especially under high common-mode voltage conditions, can obscure signal integrity and challenge even high-end measurement systems.

Reliable in-situ measurement of such signals is essential not only for design validation but also for the ongoing refinement of topologies, gate drive circuits, and protection mechanisms. Oscilloscopes, when paired with appropriately designed probes, remain the primary instruments for capturing and analyzing high-speed electrical waveforms in these environments.

Conventional oscilloscope probes convey analog signals to an oscilloscope input via a direct electrical path. These signals are then digitized and visualized for analysis. While electrical probes offer convenience and familiarity, their susceptibility to ground loop interference and common-mode transients can result in signal distortion, particularly in high-side measurements where reference potentials may float significantly.

To address these challenges, galvanically isolated probes have been developed. These systems typically incorporate a probe head for capturing differential signals, an intermediate isolation mechanism—such as optical transmission—and an electrical output interface compatible with oscilloscopes. By eliminating the direct conductive path between the probe and measurement equipment, such solutions suppress ground currents and enhance common-mode rejection, yielding cleaner signal acquisition under noisy or high-potential conditions.

Despite these advantages, optical signal transmission systems introduce a new set of engineering tradeoffs. Signal modulation techniques used to convert electrical waveforms into optical signals—especially in analog optical links—can suffer from limited bandwidth, distortion due to offset misalignment, and nonlinear attenuation behavior over temperature or mechanical stress. These impairments typically result in amplitude compression, phase shift, or transient mismatch between different portions of the signal spectrum.

Accordingly, there remains a need for improved signal transmission systems capable of preserving the full bandwidth, accuracy, and integrity of high-speed differential signals under demanding common-mode and environmental conditions. Ideally, such systems would offer robust isolation, accurate offset handling, and coordinated delay management-without compromising modulation linearity or signal fidelity.

### SUMMARY OF THE DISCLOSURE

What is needed is a signal transmission system that enables accurate, high-fidelity acquisition of differential electrical signals, particularly in environments characterized by fast switching, high common-mode voltages, and electrical noise. The system maintains galvanic isolation between the probe head and the measurement instrument while supporting broad bandwidth, low distortion, and robust common-mode rejection.

In certain embodiments, a signal transmission architecture receives and transmits an analog input signal from a device under test (DUT). The signal is processed along multiple frequency-optimized paths, such as a main path for full-bandwidth signal transmission and an auxiliary path optimized for high-accuracy low-frequency components. These signals are modulated using analog techniques such as frequency modulation (FM), amplitude modulation (AM), or other suitable schemes and transmitted across galvanically isolated links such as optical fibers.

The system includes circuitry for applying and removing analog DC offsets to ensure modulator compatibility and to prevent signal clipping. The system has delay equalization elements to align the timing of signals processed along separate paths. The recombination of these signals at the receiving end results in a full-bandwidth, high-integrity analog representation of the original signal suitable for oscilloscope-based visualization and analysis.

In some embodiments, the system supports a plurality of signal paths, allowing for modular expansion and optimization across multiple frequency bands or functional purposes. Communication and control signals are exchanged across an isolated communication channel. In some embodiments, the entire system is housed in a mechanically integrated unit with electrically isolated power domains.

The disclosed architecture provides significant improvements in measurement accuracy, noise immunity, and design flexibility, making it particularly well suited for characterizing high-speed power electronics, wide-bandgap semiconductors, and other advanced switching systems operating in electrically demanding environments.

### BRIEF DESCRIPTION OF THE DRAWINGS

The accompanying drawings illustrate several embodiments of the disclosure. Together with the description, the drawings serve to explain the principles of the disclosure.

FIG. 1 is a schematic of an exemplary system showing the signal transmission, modulation, demodulation, and reception.

FIG. 2 is a schematic of the exemplary system of FIG. 1 with a plurality of analog signal offset stages.

FIG. 3 is a schematic of an optical probing system with separate main and auxiliary analog-optical signal modulation and demodulation devices.

FIG. 4 is a schematic of an optical probing system with separate main and auxiliary analog-optical signal transmission devices and an additional communication link.

FIG. 5 is a schematic of an optical probing system with one main and two auxiliary analog-optical signal transmission devices and a communication link.

FIG. 6 is a schematic of an optical probing system having one housing with a dedicated isolation unit.

FIG. 7 is an illustration of an optical probing system.

### REFERENCE NUMERALS OF THE DRAWINGS

1 Optical probing system
3 Amplifier or damper device
5 Band-splitting filter with defined cutoff frequency
7 Low-frequency (LF) modulator device
8 Auxiliary signal component
9 High-frequency (HF) modulator device
10 Main signal component
11 LF analog signal transmitter diode (AC-coupled)
13 HF analog signal transmitter diode (AC-coupled)
15 LF fiber-optic cable
17 HF fiber-optic cable
19 LF analog signal receiver diode (AC-coupled)
21 HF analog signal receiver diode (AC-coupled)
23 LF demodulator device
25 HF demodulator device
27 Mixer or analog recombination circuit
29 Attenuator with 50-ohm or 1-megaohm termination
31 LF analog signal offset stage
33 HF analog signal offset stage
35 LF analog signal de-offset stage
37 HF analog signal offset stage
39 Analog signal input device
41 DUT
43 Input network
45 Main signal transmitter
47 Auxiliary signal transmitter
49 Main signal transmission path
51 Auxiliary signal transmission path
53 Main signal receiver
55 Auxiliary signal receiver
57 Output network
58 Differential signal
59 Interface box
60 Galvanic isolation barrier
61 Communication path
62 Fiber-optic link
63 Communication link (Probe Head side)
65 Communication link (Interface box side)
66 Communication signal component
67 Housing
69 BNC output
71 Interface box power supply
73 Analog signal output device
75 Probe head battery compartment
77 BNC-type electrical connector device
79 Power cord
81 Probe tip
83 3D-positioner stand
85 Electrically isolated socket
87 First auxiliary signal transmitter
88 First auxiliary signal component
89 Second auxiliary signal transmitter
90 Second auxiliary signal component
91 First auxiliary signal receiver
93 Second auxiliary signal receiver
95 First auxiliary signal transmission path
97 Second auxiliary signal transmission path
99 Single analog output signal

### DETAILED DESCRIPTION

The present disclosure generally provides for optical probing systems that comprise a galvanically isolated probe head which converts an electrical-analog signal to an optical-analog signal, an optical-analog analog-optical signal transmission device, and an electrical-analog signal output which is removably connectable to an oscilloscope. Exemplary probe heads are generally differential optical probe heads suitable for measuring high-frequency differential signals at a given DC-offset voltage as observed on the high-side of power modules. Typically, such probe heads comprise a probe tip with a suitable DUT connection.

In the following sections, detailed descriptions of examples of the disclosure will be given. The description of the preferred and alternative examples are exemplary only, and it is understood that to those skilled in the art that variations, modifications, and alterations may be apparent. It is therefore to be understood that the examples do not limit the broadness of the aspects of the underlying disclosure as defined by the claims.

The terms ‘high-frequency (HF)’ and ‘low-frequency (LF)’ are to be understood in a broad sense. Specifically, these terms may be understood as ‘main frequency’ and ‘secondary/auxiliary frequency’. Instead of utilizing a ‘one-size-fits-all’ modulation for different frequencies, multiple, separate frequency modulations are used and tailored to the frequency band at hand.

The analog-electrical input signal is detected on the DUT by the optical probing system analog-electrical signal input device. The analog-electrical signal may be amplified. The originally measured total analog-electrical signal is then split into analog-electrical signal component such as into a main analog-electrical signal and into an auxiliary analog-electrical signal. This may be achieved using the input device circuitry of the present disclosure. The analog-electrical signals can also be amplified and/or conditioned separately using the input device circuitry. The resulting analog-electrical signals are converted to analog-optical signals using transmitting diodes, transmitted to the analog-electrical signal output device where they are received, and converted back to analog-electrical signals along with the analog-electrical output signal.

The optical probing system may comprise an analog-electrical signal input device, a analog-electrical signal output device, and a connection between the analog-electrical signal input device and the analog-electrical signal output device.

The analog-electrical signal input device may comprise an input device circuitry, configured to split the analog-electrical signal into two signals: a main analog-electrical signal, and an auxiliary analog-electrical signal. The main analog-electrical signal may be a full bandwidth signal, which may include DC. The auxiliary analog-electrical signal may be the low-frequency and DC component of the originally measured signal. The analog-electrical signal input device may further comprise a communication signal transmission device interface that facilitates transmitting control and safety signals. The communication signal transmission device is optional.

The galvanic isolation barrier, the connection between the analog-electrical signal input device and the analog-electrical signal output device, may comprise multiple fiber-optic cables. Each fiber-optic cable may represent one analog-optical signal transmission device. The galvanic isolation barrier may comprise a connection for the main (HF) path, which may be a fiber-optic cable, a connection for the auxiliary (LF) path, which may be a fiber-optic cable, and an optional, optical communication device for control and safety signal transmission. The optical communication device comprises an analog-optical signal transmission device.

The analog-electrical signal output device may comprise an output device circuitry. The output device circuitry may be configured analogous to the input device circuitry. For example, the output device circuitry may connect a main signal receiving diode, an auxiliary signal receiving diode, a control signal receiving diode.

The exemplary embodiments in the figures present the system architecture components in recommended order along a galvanically isolated signal path from a DUT to an analog output signal device such as an oscilloscope and is optimized for signal reception, filtration, modulation, transmission, recombination, demodulation, and output. Other orders and input/output devices may be considered. However, the system of the disclosure is preferred for fast and complete DUT signal transmission to an analytical device, especially an oscilloscope. The system improves signal integrity and robustness over conventional single-path optical transmission systems.

### DETAILED DESCRIPTIONS OF THE DRAWINGS

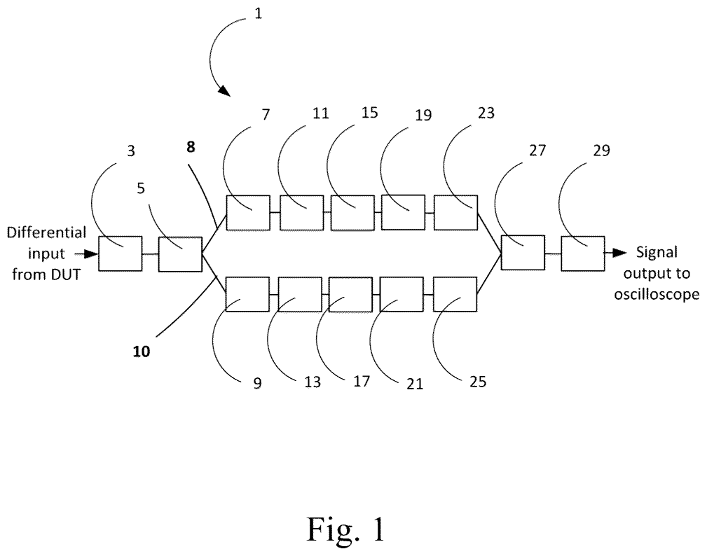

Referring now to FIG. 1, an embodiment of a signal transmission system 1 is shown. The system 1 is configured to receive a differential input signal from a device under test (DUT) and transmit that signal to an analog signal output device such as an oscilloscope via frequency-band separation, optical modulation, and recombination, while preserving high signal fidelity and isolation.

The differential input signal is first received at an amplifier or damper 3, which may amplify or attenuate the incoming signal depending on its amplitude. The conditioned signal is then passed to a band-splitting filter 5.

The band-splitting filter 5 may be configured to separate the differential input signal into an auxiliary signal component 8 which may also be a low-frequency component and a main signal component 10 which may be a high-frequency component based on a designated cutoff frequency. In one embodiment, the cutoff frequency is approximately 20 kHz, although other values may be selected depending on the intended application or system bandwidth. The filter may implement a transition band or dual corner frequencies to ensure minimal insertion loss and signal degradation at the interface between the low-frequency and high-frequency signal paths. The filter characteristics are selected to preserve phase and amplitude fidelity across the entire signal spectrum while ensuring effective separation of the frequency components for respective modulation and transmission.

The LF component is directed to an LF modulator 7, which modulates the LF signal for optical transmission. The modulated signal is then transmitted via an LF analog signal transmitter diode 11, which comprises an AC-coupled light source (e.g., laser diode or LED) that converts the modulated electrical signal into an optical signal. This optical signal is transmitted through an LF fiber-optic cable 15 to an LF analog signal receiver diode 19, which comprises an AC-coupled photodiode that converts the incoming optical signal back into an electrical signal. The electrical signal is then demodulated by an LF demodulator 23 to recover the low-frequency signal component.

The analog modulation technique used in the auxiliary signal path may include, but is not limited to, frequency modulation (FM), amplitude modulation (AM), phase modulation (PM), pulse width modulation (PWM), pulse frequency modulation (PFM), or pulse density modulation (PDM). These modulation schemes are advantageous for conveying precision amplitude or timing information and may be selected based on the nature of the signal and the desired fidelity. The auxiliary path may also transmit reference waveforms or other analog content outside the primary signal bandwidth for calibration or correction purposes. In certain embodiments, the primary signal path utilizes an amplitude-modulated analog signal, while the auxiliary path employs a complementary analog modulation format, such as FM, PM, or PWM, to mitigate the effects of attenuation drift, DC offset, or gain variation that may occur in the primary path due to changes in fiber alignment, movement, temperature, or component aging.

In this configuration, the LF or auxiliary signal path may not support the full bandwidth of the input signal, but it carries high-accuracy information used to reconstruct or stabilize the output. For example, the auxiliary signal may be used to correct variations in the main signal path such as offset drift, gain inaccuracies, or bandwidth non-uniformity. When combined in the mixer or analog recombination circuit 27, the main and auxiliary paths enable a higher overall signal fidelity than could be achieved using a single analog transmission path alone. The recombination circuit thus integrates both the high-speed main content and the high-integrity auxiliary content to generate a comprehensive and corrected analog output for oscilloscope-based analysis. Concurrently, the HF component is routed to an HF modulator 9, modulated, and passed to an HF analog signal transmitter diode 13, which converts the modulated HF signal into an optical signal. The optical signal is transmitted through an HF fiber-optic cable 17 to an HF analog signal receiver diode 21, which performs optical-to-electrical conversion. The output is processed by an HF demodulator 25 to recover the high-frequency signal content.

Modulation may occur via different modulation techniques. Instead of injecting the modulated HF signal and the modulated LF signal into their respective optical fiber, a common optical fiber may be used. An LF signal path can be used to correct gain, drift, offset, or bandwidth distortion in the HF path.

The demodulated LF and HF signals are then delivered to a mixer or analog recombination circuit 27, which reconstructs the full-bandwidth signal in the analog domain. The recombined signal is then passed through an attenuator 29, which is configured for either 50-ohm or 1-megaohm termination, depending on the impedance requirements of the connected oscilloscope or measurement instrument.

Providing the two signal paths separately-whether via one or multiple optical fibers-offers the advantage of more efficient and independent tuning. This enables higher DC accuracy and improved flatness in the low-frequency domain, as adjustments can be made without impacting the high-frequency signal. As a result, the system achieves an extended overall bandwidth by allowing each path to be independently optimized for its respective frequency range.

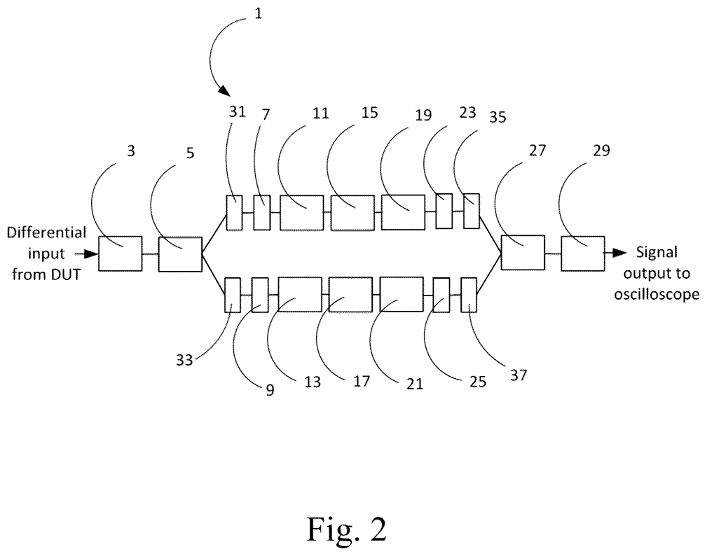

Referring now to FIG. 2, a variation of the exemplary embodiment of FIG. 1 is shown. The variant disclosed in FIG. 2 includes dedicated analog offset and de-offset stages in both the low-frequency (LF) and high-frequency (HF) signal paths to accommodate modulation constraints and optimize signal linearity across the optical link.

In the low-frequency domain, the LF signal is directed to an LF analog signal offset stage 31, which applies a predefined offset or level-shift to the signal. This ensures compatibility with the subsequent modulation stage and prevents clipping during laser diode current modulation. The offset-adjusted signal is then passed to the LF modulator 7 and subsequently to the LF analog signal transmitter diode 11, which is AC-coupled and configured to convert the modulated LF electrical signal into an optical signal. The optical signal is transmitted via an LF fiber-optic cable 15 to an LF analog signal receiver diode 19, which converts the optical signal back into the electrical domain. The resulting signal is demodulated by an LF demodulator 23 and then passed through an LF analog signal de-offset stage 35, which removes the earlier-applied offset and restores the signal to its original baseline.

In the high-frequency domain, the HF signal is routed through an HF analog signal offset stage 33, which performs an analogous offset operation to prepare the HF signal for high-speed optical modulation. The offset signal is then processed by the HF modulator 9 and converted into an optical signal by the HF analog signal transmitter diode 13. The HF optical signal is transmitted via an HF fiber-optic cable 17 to an HF analog signal receiver diode 21. After photodetection, the electrical signal is demodulated by an HF demodulator 25, followed by an HF analog signal de-offset stage 37, which reverses the applied offset and restores the original signal level.

The offset or level-shift, as well as the analogous offset operation may be a voltage offset, also referred to as DC Bias Shift. This DC bias may be added to center the signal. (e.g., shifting-2V to +2V signals into a 0-4V window). After demodulation, the bias is subtracted to restore the original signal levels.

The outputs of the LF and HF de-offset stages (35 and 37, respectively) are combined in a mixer or analog recombination circuit 27 to reconstruct the full-bandwidth signal. This composite signal is then delivered to an attenuator 29, which may be configured for 50-ohm or 1-megaohm termination to match the impedance of the connected measurement instrument.

In certain embodiments, the system further comprises delay equalization stages disposed proximate to the mixer or analog recombination circuit 27. These may include one or more first-order (PT1) or second-order (PT2) analog filter elements configured to compensate for runtime differences between the low-frequency and high-frequency signal paths. Such differences may arise from unequal propagation delays caused by variations in optical diode characteristics, fiber length, or modulator response times.

The delay equalization stages may be implemented before, after, or integrated within the recombination circuit 27, and may comprise passive or active analog filters designed to align signal arrival times and preserve phase coherence between frequency components. In one embodiment, the LF path is delayed slightly using a PT1 filter to match the faster HF optical transmission channel. In another embodiment, the HF path incorporates a PT2 element to balance group delay and bandwidth simultaneously.

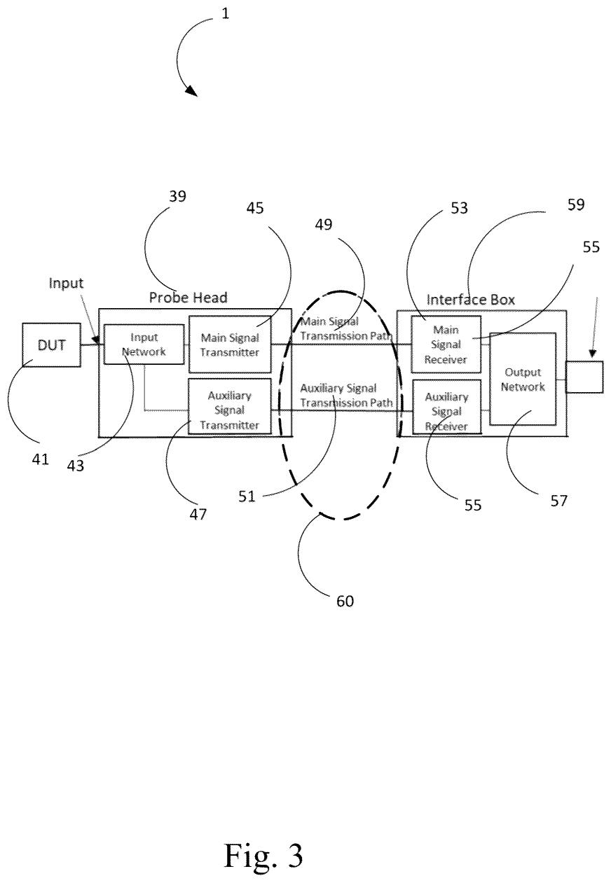

Referring now to FIG. 3, a generalized embodiment of the signal transmission architecture shown in FIGS. 1 and 2 is illustrated. The system comprises a probe head 2 and an interface box connected via optical transmission paths. The probe head receives an input signal from a device under test (DUT) 41 through an input network 43, which may include signal conditioning, amplification, attenuation, and frequency separation functionality as described with respect to FIGS. 1 and 2.

The input signal is processed in parallel by a main signal transmitter 45 and an auxiliary signal transmitter 47. The main signal transmitter 45 corresponds functionally to the high-frequency (HF) signal path, including an analog signal offset stage, a high-frequency modulator, and an optical transmitter. The auxiliary signal transmitter 47 corresponds functionally to the low-frequency (LF) signal path, including a low-frequency offset stage, low-frequency modulator, and LF optical transmitter.

The main signal and auxiliary signal are transmitted respectively via a main signal transmission path 49 and an auxiliary signal transmission path 51, which may comprise optical fibers, as previously described. These signals are received in the interface box by a main signal receiver 53 and an auxiliary signal receiver 55, which correspond respectively to the HF and LF photodetectors, demodulators, and de-offset stages described with respect to FIGS. 1 and 2.

In the main signal path, the input network 43 is designed to interface directly with the device under test (DUT) 41 and to condition the received differential input signal for high-fidelity transmission to the receiver circuitry. The input network 43 may include a wideband amplifier, attenuator, or other active or passive circuitry suitable for adapting the signal level and impedance to the transmission system. Importantly, the main path is configured to preserve the full bandwidth of the incoming signal, including high-speed transient and frequency content, and is therefore optimized for linearity and bandwidth rather than filtering or precision scaling.

The output of the input network 43 is routed through the main signal transmitter 45, which prepares the signal for optical or galvanically isolated transmission via the main signal transmission path 49, ultimately reaching the main signal receiver 53. The output stage of the input network may be specifically adapted to interface with the transmitter or modulator input, ensuring signal integrity and impedance matching across the system boundary. This enables the system to deliver the full-bandwidth content of the DUT signal to the oscilloscope or measurement device for high-speed waveform acquisition and analysis.

The auxiliary signal transmission path 51 may be configured to connect the input network 43 and provide a high-accuracy version of the input signal. This version of the signal is transmitted to the receiving end (interface box side) using an analog modulation technique such as FM, AM or PM, PWM, PFM, PDM, or other analog modulation that can preserve the accuracy of the signal, but which may not be able to support the full bandwidth of the input signal.

The split path amplifier design allows for independent optimization of each path, ensuring optimal performance for the needed high-speed and low-frequency signals, and less influenced by environmental factors. Accordingly, the design may include circuitry for selecting between the paths (n+1) based on the input signal characteristics or user-defined preferences.

The recovered signals are combined in an output network 57, which may further include analog recombination circuitry, delay equalization stages (e.g., PT1/PT2), and an attenuator for interfacing with standard test equipment input impedances (e.g., 50 ohm or 1 megaohm).

In a preferred embodiment, both the main signal transmission path 49 and the auxiliary signal transmission path 51 are implemented using optical fiber, thereby providing galvanic isolation and enabling high-fidelity signal transmission over extended distances with minimal electromagnetic interference. The main and auxiliary signals may be transmitted over separate optical fibers, or alternatively, multiplexed over a single optical fiber using wavelength division multiplexing (WDM) or other multiplexing techniques, such as polarization, time-domain, or mode-division separation.

While optical fiber is the preferred transmission medium, other galvanically isolated transmission methods may also be employed, including but not limited to: transformer-coupled links, wireless transmission, microwave transmission, or modulation-based techniques such as mixer-based up conversion, quadrature amplitude modulation (QAM), or related analog or digital encoding schemes. These alternatives may be suitable depending on system-level tradeoffs in bandwidth, complexity, cost, or mechanical integration.

Furthermore, although the embodiments disclosed above primarily describe separate transmission channels for the main signal, auxiliary signal, and communication path, these three paths (Main, Auxiliary, and Communication) may, in some implementations, be transmitted over a single medium, such as a shared optical fiber or radio-frequency link, using suitable multiplexing or modulation techniques. Conversely, dedicated physical separation, such as three individual optical fibers or more generally n+1 isolated transmission paths, remains within the scope of the present disclosure and may offer advantages in signal integrity, isolation, or system modularity.

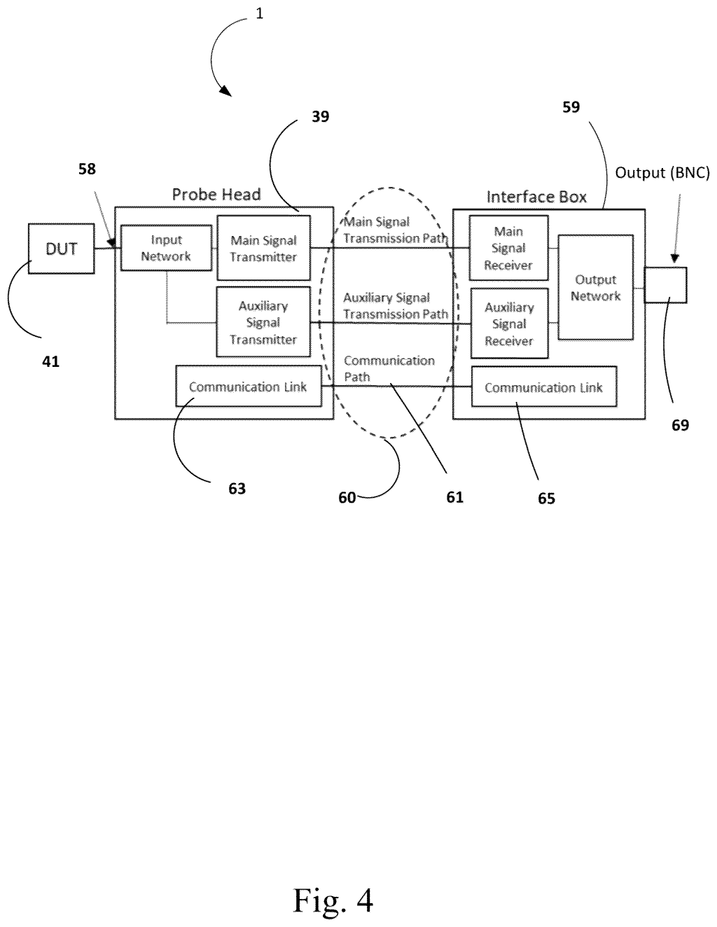

Referring now to FIG. 4, a further embodiment of the signal transmission system is illustrated. FIG. 4 builds upon the embodiment described in FIG. 3 by incorporating a bidirectional communication channel across the galvanic isolation barrier to support auxiliary control, synchronization, and configuration signaling between the probe head and the interface box.

As in the previous embodiment, a differential signal 58 is received from a device under test (DUT) 41 and routed through an input network 43 located within a probe head. The input network 43 may include impedance matching circuitry, filtering, and signal conditioning components (not shown). The conditioned signal is split and provided in parallel to a main signal transmitter 45 and an auxiliary signal transmitter 47.

The main signal transmitter 45 is configured to transmit the high-frequency (HF) component of the signal via a main signal transmission path 49 to a main signal receiver 53 within the interface box. Similarly, the auxiliary signal transmitter 47 transmits the low-frequency (LF) component of the signal over an auxiliary signal transmission path 51 to an auxiliary signal receiver 55.

The recovered signals are combined and processed in output network 57, as previously described. In the embodiment of FIG. 4, the system further comprises a communication path 61 that spans the galvanic isolation barrier and facilitates exchange of control, calibration, timing, and/or diagnostic data between the probe head and the interface box.

On the probe head side, a communication link 63 is provided to send or receive such data across communication path 61. On the interface box side, a corresponding communication link 65 is provided. Communication path 61 may be implemented using an optically isolated digital communication channel, a wireless interface, or other galvanically isolated interface.

The communication system may operate independently of the main and auxiliary signal transmission paths to support calibration routines, gain or offset control, runtime diagnostics, synchronization pulses, probe identification, or other system-level functions. This bidirectional communication architecture enhances flexibility, configurability, and reliability in measurement scenarios requiring adaptive control or closed-loop behavior.

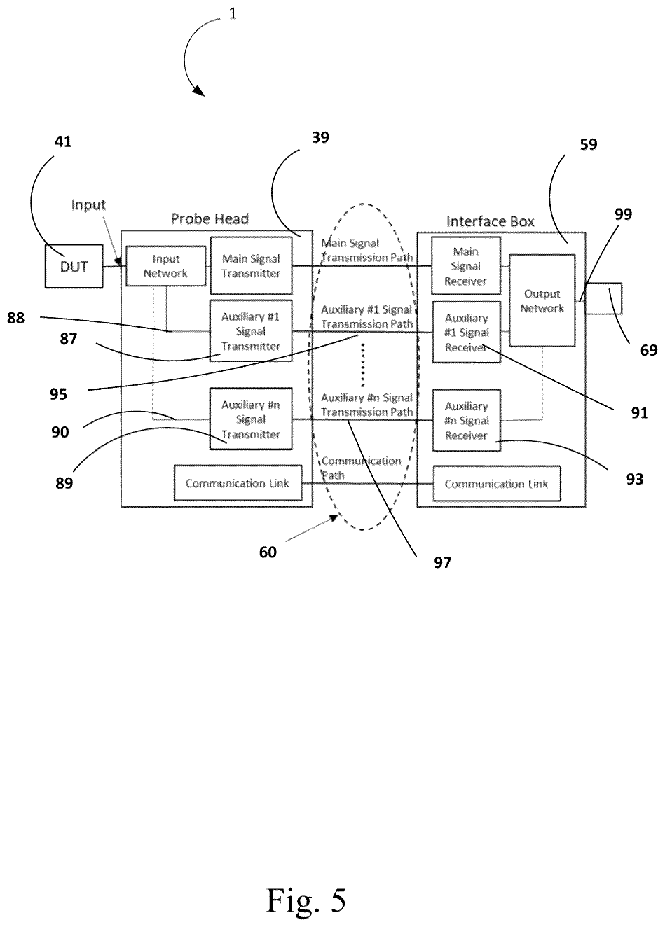

Referring now to FIG. 5, a generalized embodiment of the signal transmission system is shown. FIG. 5 builds upon the two-path architecture of FIGS. 1 and 2 and the modular framework of FIGS. 3 and 4 and introduces the capability to split and process the input signal into n distinct signal transmission paths, where n is an integer greater than or equal to one. This generalized architecture enables enhanced flexibility, scalability, and signal fidelity in scenarios where more than two frequency bands or signal components must be captured and transmitted independently. For example, the transmission, transmission path, and receiver of a first and of a second auxiliary signal are shown (87, 89, 91, 93, 95, 97) along with the main signal and communication path components.

As in previous embodiments, a differential signal is received from a device under test (DUT) via an input network 43 located within a probe head. The input network 43 may include impedance matching, filtering, attenuation, and frequency band-separation circuitry. The processed signal is then split and provided to a main signal transmitter 45 and a plurality of auxiliary signal transmitters. Each transmitter is configured to process and modulate a specific sub-band or component of the overall signal.

The main signal and each auxiliary signal are transmitted across corresponding optical or galvanically isolated signal transmission paths. In the illustrated embodiment, these include a main signal transmission path 49 and auxiliary signal transmission paths. These transmission paths may comprise optical fibers, RF links, or other isolated communication media.

On the interface box side, the signals are received by a corresponding set of receivers, including a main signal receiver 53 and auxiliary signal receivers. Each receiver performs optical-to-electrical conversion, demodulation, and optional signal restoration (e.g., offset removal or delay equalization), as previously described in connection with FIGS. 1 and 2.

The resulting signal components are provided to an output network 57, which may include summing circuitry, delay alignment, gain control, and impedance matching. The output network reconstructs the full-bandwidth signal in the analog domain as a single analog output signal transmitted to an analog signal output device. However, the output network may optionally delivers the components separately to an analog signal output device.

A communication path 61 and corresponding communication links 63 and 65 (located in the probe head and interface box, respectively) are also included to facilitate bidirectional exchange of control, configuration, synchronization, and diagnostic information across the galvanic isolation barrier. These may operate independently of the signal transmission paths.

The architecture shown in FIG. 5 allows for modular extension of the transmission system. For example, in one embodiment, the signal may be split into three or more frequency bands using an extended band-splitting filter and routed to corresponding transmission paths. In other embodiments, auxiliary channels may be reserved for specialized monitoring functions, noise analysis, common-mode tracking, or differential signal validation. One embodiment may include circuitry for selecting between the paths (n+1) based on the input signal characteristics or user-defined preferences

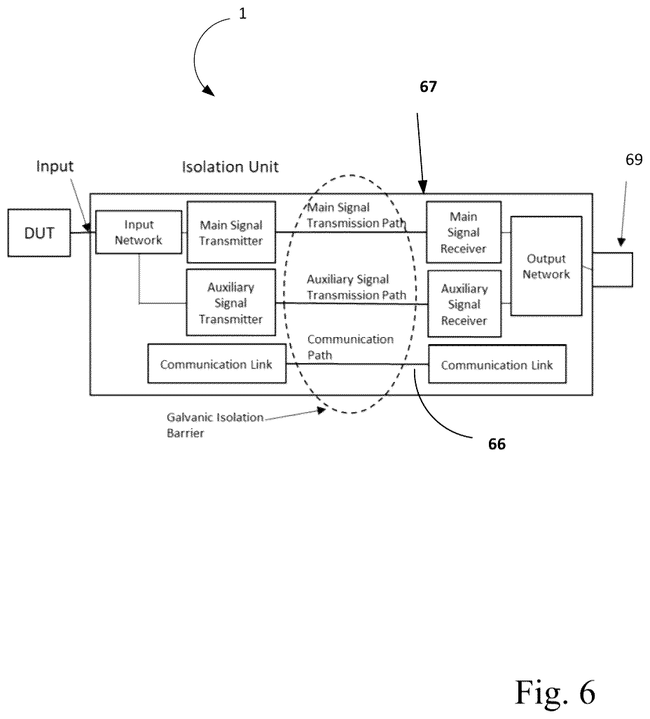

Referring now to FIG. 6, a further embodiment of the signal transmission system is shown. FIG. 6 builds upon the system architecture described in FIGS. 3 through 5 by incorporating a single physical housing 67 encompassing both the signal transmission and reception circuitry, while maintaining the galvanic isolation barrier 60 between the DUT side and the output side of the system.

In the illustrated embodiment, the signal transmission system is enclosed within a unitary housing that forms part of a compact isolation unit. The isolation unit includes an input interface configured to receive analog signals from a device under test (DUT). The DUT signal is routed to an input network 43, which may perform impedance matching, attenuation, and band-splitting functions as described with respect to previous embodiments.

The input signal is then routed to a main signal transmitter 45 and an auxiliary signal transmitter 47, which respectively process the high-frequency and low-frequency (or otherwise separated) signal components. These components are transmitted across respective main and auxiliary signal transmission paths, indicated collectively at 49 and 51, which cross the galvanic isolation barrier and connect to corresponding main and auxiliary signal receivers 53 and 55.

As in FIG. 4, a communication path 61 and associated communication links 63 and 65 are provided to enable bidirectional exchange of control, configuration, and diagnostic data between the isolated probe-side circuitry and the output-side processing circuitry via a transmitted communication signal component 66. This communication path is galvanically isolated from the main and auxiliary signal domains, and may be implemented optically, capacitively, or wirelessly.

The housing 67 provides mechanical protection and environmental shielding for all components while maintaining distinct electrical domains on either side of the galvanic isolation barrier. In some embodiments, the housing may be implemented as a two-part shell or multi-compartment enclosure, physically dividing the transmitter and receiver sections while maintaining optical or isolated signal paths between them.

The processed and recombined signal is routed through an output network 57, which provides final signal conditioning and impedance matching before delivering the signal to an output interface such as a BNC connector. The output interface is electrically isolated from DUT input, making the system well-suited for probing high-voltage environments or systems with floating ground potentials.

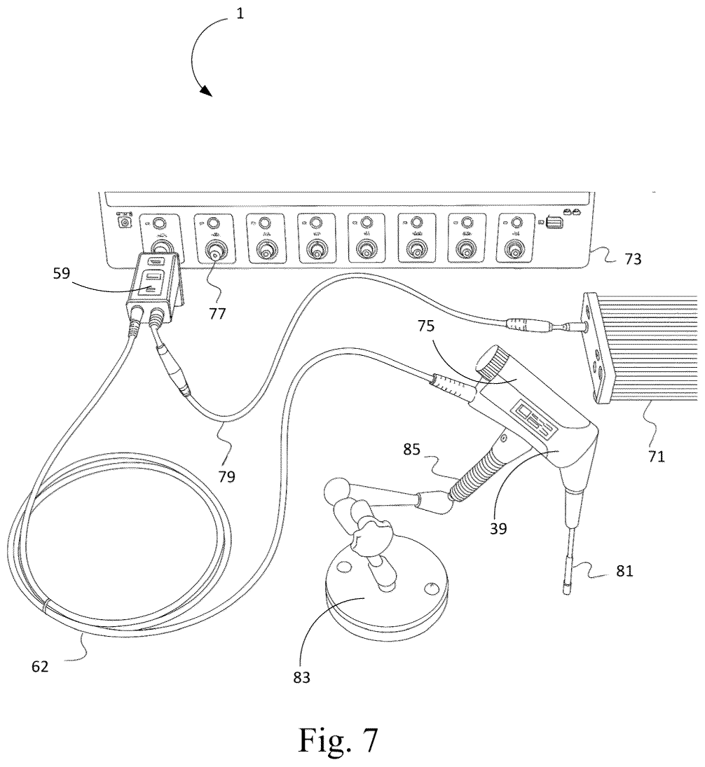

Referring now to FIG. 7, an exemplary implementation of an optical probing system 1 is illustrated. The system is consistent with the architectural embodiments shown and described in FIGS. 1 through 6 and is depicted in an applied configuration involving an analog signal input device such as an optical probe head 39, a fiber-optic link 62, an interface box 59, a power supply for the interface box 71, and an oscilloscope 73. The probe head comprises a probe tip 81, which is configured to be brought into contact with a DUT (not shown). The probe head is held in place via an adjustable 3D-positioner 83, comprising an electrically isolated socket 83.

In the illustrated embodiment, a probe head 39 includes a housing containing the analog signal conditioning and transmission circuitry, including a main signal transmitter and one or more auxiliary signal transmitters as described previously. The probe head 39 is configured to be galvanically isolated from the measurement equipment and power grid, and in this example, is powered by a battery, inserted into the probe head battery compartment 75. This local power source allows the probe head 39 to remain electrically isolated while still powering internal components such as analog signal offset stages, modulators, and optical transmitters. According to an alternative embodiment, a power-over-fiber adapter may be inserted into the probe head battery compartment instead of a battery, allowing continuous operation of the probe head whilst maintaining galvanic isolation.

The probe head is optically coupled to the interface box 59 via one or more fiber-optic cables, provided inside the fiber-optic link 62. These one or more fiber-optic cables form the main and auxiliary signal transmission paths that span the galvanic isolation barrier. These paths correspond to the optical links described in FIGS. 1-6. The interface box 59 includes main and auxiliary signal receivers, a communication link, and an output network, as previously described. In this implementation, the interface box is connected to an oscilloscope using a BNC-type electrical connector 77, allowing the recovered and recombined signal to be displayed, analyzed, or logged.

The interface box 59 is powered by an external power supply 71, which is connected to the interface box 59 via a power cord 79. This power supply provides the necessary electrical power to operate the receiver circuitry, demodulators, delay equalization elements, recombination circuits, and output driver stages. The system architecture thus supports fully isolated signal acquisition with power supplied independently to the probe head and the interface box.

The embodiment shown in FIG. 7 serves as an illustrative example of how the modular optical probing architecture disclosed in earlier figures may be implemented in a real-world laboratory or test environment. The combination of galvanic isolation, independent power domains, optical signal paths, and standard output interfaces such as BNC enables the system to safely and accurately capture signals in high-voltage, high-speed test conditions.

### CONCLUSION

Although the disclosure has been described in terms of exemplary embodiments, the disclosure is not limited thereto. This description of the exemplary embodiments is set to be understood in connection with the figures of the accompanying drawings, which are to be considered part of the entire written description. Relative terms such as “lower,” “upper,” “horizontal,” “vertical,” “above,” “below,” “up,” “down,” “top,” “bottom,” “back,” and “front” as well as derivatives such as “horizontally,” “downwardly,” and “upwardly,” should be construed to refer to the orientation as then described or as shown in the particular figure under discussion. These relative terms are for convenience of description and do not require that the probe head be constructed or operated in a particular orientation. Terms concerning attachments and coupling such as “connected” refer to a relationship wherein structures are secured or attached to one another either directly or indirectly through intervening structures, as well as both movable or rigid attachments or relationships, unless expressly described otherwise.

While this specification contains many specific implementation details, these details should not be construed as limitations on the scope of any disclosures or of what may be claimed. It should be understood that these exemplary embodiments may be susceptible to various modifications and may be present in alternative forms. All statements herein reciting principles, aspects, and embodiments of the disclosure are intended to encompass both the structural and the functional equivalents thereof. Additionally, it is intended that such equivalents include both currently known equivalents and any elements developed in the future that perform the same function regardless of structure. The claims are not intended to be limited to the embodiments, modifications, and alternative forms disclosed but are intended to cover all modifications, equivalents, and alternatives falling within the spirit and scope of the disclosure.

What is claimed is:

1. An optical probing system, comprising:
an analog signal input device comprising an input network, a main signal transmitter, and an auxiliary signal transmitter;
an analog signal output device;
a galvanic isolation barrier through which an HF main signal transmission path and an LF auxiliary signal transmission path traverse from the analog signal input device to the analog signal output device; and
an interface box comprising a main signal receiver, an auxiliary signal receiver, and an output network.

2. The system of claim 1, wherein the analog signal input device is configured to:
receive a differential signal from a DUT,
separate the differential signal into an auxiliary signal component and a main signal component,
transmit the main signal component via an HF fiber-optic cable on the HF main signal transmission path, and
transmit the auxiliary signal component via an LF fiber-optic cable on the LF auxiliary signal transmission path to the interface box.

3. The system of claim 1, wherein the analog signal input device further comprises:
an amplifier or damper that conditions a differential signal.

4. The system of claim 1, wherein the LF signal component has a lower bandwidth than the HF signal component and is used to correct, gain, offset, or supplement frequency response variations in the HF signal.

5. The system of claim 1, wherein the analog signal input further comprises an LF analog offset stage and an HF analog de-offset stage.

6. The system of claim 1, wherein the interface box further comprises an LF analog offset stage and an HF analog de-offset stage.

7. The system of claim 1, wherein the interface box further comprises a recombination circuit configured to align and mix the LF and HF signal components to analog.

8. The system of claim 1, further comprising wherein a communication signal on a galvanically isolated communication path traverses from an analog signal input device communication link to an analog signal output device communication link.

9. The system of claim 1, wherein the analog signal input device is a probe head, and the analog signal output device is an oscilloscope.

10. The system of claim 1, wherein the analog input device further comprises an auxiliary LF signal transmitter diode coupled to the LF fiber optic cable and a main HF signal transmitter diode coupled to the HF fiber optic cable.

11. The system of claim 1, wherein the interface box output network further comprises an auxiliary LF signal receiver diode coupled to the LF fiber optic cable and a main HF signal receiver diode coupled to the HF fiber optic cable.

12. The system of claim 10, wherein the auxiliary LF signal transmitter diode deploys a first analog modulation technique.

13. The system of claim 10 wherein the main HF signal receiver diode deploys a second analog modulation technique.

14. The system of claim 11, wherein the auxiliary LF signal transmitter diode deploys a first analog modulation technique.

15. The system of claim 11, wherein the main HF signal receiver diode deploys a second analog modulation technique.

16. The system of claim 12, wherein the first modulation technique is frequency modulation (FM), phase modulation (PM), pulse width modulation (PWM), or pulse density modulation (PDM).

17. The system of claim 14, wherein the first modulation technique is frequency modulation (FM), phase modulation (PM), pulse width modulation (PWM), or pulse density modulation (PDM).

18. The system of claim 13, wherein the second modulation technique is amplitude modulation (AM).

19. The system of claim 15, wherein the second modulation technique is amplitude modulation (AM).

20. The system of claim 15, wherein the interface box output network further comprises an analog recombination circuit that combines the main HF signal and the auxiliary LF signal into a single analog output.
